(19) United States
(12) Patent Application Publication
(10) Pub. No.: US 2013/0240996 A1
(43) Pub. Date: Sep. 19, 2013

(54) Semiconductor Device and Method of Manufacturing the Same

(71) Applicants: Huaxiang Yin, Beijing (CN); Qiuxia Xu, Beijing (CN); Chao Zhao, Beijing (BE); Dapeng Chen, Beijing (CN)

(72) Inventors: Huaxiang Yin, Beijing (CN); Qiuxia Xu, Beijing (CN); Chao Zhao, Beijing (BE); Dapeng Chen, Beijing (CN)

(21) Appl. No.: 13/520,611

(22) PCT Filed: Apr. 11, 2012
(86) PCT No.: PCT/CN12/00486

§ 371 Date: Jul. 5, 2012

(30) Foreign Application Priority Data
Mar. 14, 2012 (CN) 201210067312.5
Apr. 11, 2012 (CN) PCT/CN2012/000486

(51) Int. Cl. H01L 27/088; H01L 21/336

(52) U.S. Cl. 257/368; 438/287; 257/E27.06; 257/E21.409

(57) ABSTRACT

The present invention discloses a semiconductor device, comprising a substrate, a plurality of gate stack structures on the substrate, a plurality of gate spacer structures on both sides of each gate stack structure, a plurality of source and drain regions in the substrate on both sides of each gate spacer structure, the plurality of gate spacer structures comprising a plurality of first gate stack structures and a plurality of second gate stack structures, wherein each of the first gate stack structures comprises a first gate insulating layer, a first work function metal layer, a second work function metal diffusion blocking layer, and a gate filling layer, the work function is close to the valence band (conduction band) edge; each of the second gate stack structures comprises a second gate insulating layer, a modified first work function metal layer, a second work function metal layer, and a gate filling layer, characterized in that the second work function metal layer comprises implanted work function-regulating doped ions, which are simultaneously diffused to the first work function layer below to regulate the threshold such that the work function of the gate is close to the valence band (conduction band) edge and is opposite the original first work function, to thereby regulate the work function accurately.

### CROSS REFERENCE

This application is a National Stage application of, and claims priority to, PCT Application No. PCT/CN2012/000486, filed on Apr. 11, 2012, entitled ‘SEMICONDUCTOR DEVICE AND METHOD OF MANUFACTURING THE SAME’, which claimed priority to Chinese Application No. CN 201210067312.5, filed on Mar. 14, 2012. Both the PCT Application and Chinese Application are incorporated herein by reference in their entireties.

### FIELD OF THE INVENTION

The present invention relates to a semiconductor device and a method of manufacturing the same, more particularly, to a MOSFET for regulating a work function by metal implantation and a method of manufacturing the same.

### BACKGROUND OF THE INVENTION

Starting from the 45 nm CMOS integrated circuit technology, with continuous reduction in the device feature size, the equivalent oxide thickness (EOT) of a gate insulating dielectric layer in a CMOS device must be reduced synchronously to suppress the short channel effect. However, the ultra-thin (e.g., 10 nm) conventional oxide layer or oxynitride layer may result in severe gate current leakage since the (relative) dielectric constant is not high (e.g., about 3.9) and the insulating capability can hardly endure the relatively high field strength in such an ultra-small device. Hence, a conventional polysilicon/SiON system is no longer applicable.

In view of the foregoing, high-K (HK) dielectric materials have been started to be used to manufacture a gate insulating dielectric layer in the industry. However, the interfacial charges and polarization charges of high-K materials will cause difficulty in regulating the threshold of a device, and the combination of polysilicon and high-K materials will produce a Fermi-level pinning effect, thus such combination of polysilicon and high-K materials can not be used for regulating the threshold of a MOSFET, accordingly, the gate electrode shall employ different metal materials to regulate the threshold of a device, that is, using a metal gate (MG)/HK structure.

Metal electrodes of different work functions are needed for regulating the threshold of different MOSFETs, e.g., a NMOS and a PMOS. The regulation method using a single metal gate material may be adopted, but the range of regulation is limited. In an example of a planar SOI multi-gate device with lower standby power employing a single metal gate material, to correspond to a work function of 4.1 eV of n+ polysilicon and a work function of 5.2 eV of p+ polysilicon, an appropriate metal electrode may be selected such that the work function of the gate can be in the vicinity of the median value of the two, e.g., to be 4.65 eV or 4.65±0.3 eV. However, the device threshold is hard to be effectively controlled by such a fine regulation within a small range. The optimal process is to adopt gate electrodes of different metal materials, for example, conduction-band metal is used for the NMOS and valence-band metal is used for the PMOS such that the gate work functions of the NMOS and the PMOS can be located at the edges of the conduction band and the valence band, respectively, e.g., 4.1±0.1 eV and 5.2±0.1 eV, respectively. A detailed study of selection of the materials for these gate metal (including metal nitride) has been made in the industry, and no more unnecessary details will be provided here.

FIG. 1 illustrates a CMOSFET having a typical MG/HK structure under the manufacturing process of 45/32 nm by Intel Corporation, the left part is a PMOS, and the right part is a NMOS. Although the two parts are displayed to be adjacent to each other in the figure, they may have many intermediate separation elements in an actual layout, thus shall be specifically set depending on the design requirements in the layout, and likewise below. Particularly, the CMOS comprises a substrate 1, shallow trench isolations (STIs) 2, source and drain regions 3, source and drain extension regions 4, gate spacers 5, metal silicide layers 6 on the source and drain regions, a contact etch stop layer (CESL) 7, an interlayer dielectric layer (ILD) 8, gate insulating layers 9, gate conductive layers 10, and source and drain contacts 11. Wherein the source and drain regions 3 are preferably embedded stressed source and drain regions, for example, (raised) SiGe for a PMOS, and Si:C for a NMOS. The gate insulating layers 9 preferably comprise a multi-layer stack structure, for example, low-K (LK) interface layers such as SiO₂ and high-K (HK) insulating dielectric layers such as Hf based oxide (for example, HfO₂ etc.), wherein the interface layers are used to optimize the interfaces between the gate insulating layers and the channels in the the substrate to reduce the defects.

The gate conductive layers 10 preferably comprise a multi-layer stack structure, for example, a gate material layer 10a made from TiN for regulating a work function, a gate blocking layer 10b made from TaN etc. for selectively controlling gate filling, and a gate filling layer 10c made from TiAl etc. Wherein the gate conductive layer 10 of the PMOS comprises the above 10a, 10b and 10c, while the gate conductive layer 10 of the NMOS only comprises 10a and 10c, and in the NMOS, Al is diffused into the TiN layer to thereby form an TiAl/TiN—Al laminated structure. The CMOS device adjusts the depth of Al atoms in the TiAl layer being diffused into the TiN layer by a thickness ratio between the layer 10a and layer 10c, to thereby regulate the work function. Al being diffused into the HK insulating dielectric layer or being away from the HK insulating dielectric layer (equivalent to pure TiN metal gate) will both result in the work function to be increased and to be adaptive to a PMOS, while only Al being located at an upper part close to the HK insulating dielectric layer/TiN interface can result in a lower work function and be adaptive to an NMOS.

However, such a method of regulating a work function depending on the control of the thickness ratio of thin-films only is no longer adaptive to ultra-thin and ultra-small devices due to greater instability in the process when thin-films have the thickness of a nano-scale, thus it is hard to reasonably optimize and control the threshold regulation of small-size devices.

### SUMMARY OF THE INVENTION

As stated above, an object of the present invention is to provide a new type of CMOSFET capable of regulating a metal gate work function and a method of manufacturing the same.

Therefore, the present invention provides a semiconductor device, comprising a substrate, a plurality of gate stack structures on the substrate, a plurality of gate spacer structures on both sides of each gate stack structure, a plurality of source and drain regions in the substrate on both sides of each gate spacer structure, the plurality of gate stack structures comprising a plurality of first gate stack structures and a plurality of second gate stack structures, wherein each of the first gate stack structures comprises a first gate insulating layer, a first work function metal layer, a second work function metal diffusion blocking layer, and a gate filling layer, each of the second gate stack structures comprises a second gate insulating layer, a first work function metal layer, a second work function metal layer, and a gate filling layer, characterized in that the second work function metal layer comprises implanted work function-regulating doped ions, and the work function-regulating doped ions diffuse into the first work function layer to jointly change the work function of the second gate stack structure, such that the second gate work function of the second gate stack structure is opposite to the first gate work function of the first gate stack structure.

Wherein the first gate work function is close to the valence band and the second gate work function is close to the conduction band, or the first gate work function is close to the conduction band and the second gate work function is close to the valence band.

Wherein the first and/or the second gate insulating layer comprises at least one of silicon oxide, nitrogen-doped silicon oxide, silicon nitride, and high-K materials. Wherein the high-K materials include Hf-based materials selected from HfO₂, HfSiOₓ, HfSiON, HfAlOₓ, HfTaOₓ, HfLaOₓ, HfAlSiOₓ, and HfLaSiOₓ, rare-earth based high-K dielectric materials selected from ZrO₂, La₂O₃, LaAlO₃, TiO₂, and Y₂O₃, Al₂O₃, or a composite layer of the above materials.

Wherein the first work function metal layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La.

Wherein the second work function metal diffusion blocking layer comprises at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W.

Wherein the gate filling layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La; and/or c) metal silicide, including at least one of CoSi₂, TiSi₂, NiSi, PtSi, NiPtSi, CoGeSi, TiGeSi, and NiGeSi; and/or d) metal oxide conductor, including at least one of In₂O₃, SnO₂, ITO, and IZO; and/or e) semiconductor materials, including at least one of doped polysilicon, amorphous silicon, polycrystalline germanium, and polycrystalline silicon-germanium; or a composite layer of the above materials.

Wherein as for a NMOS, the work function-regulating doped ions comprise at least one of Al, Ga, In, and B; as for a PMOS, the work function-regulating doped ions comprise at least one of Sb, As, P, N, and Ar.

Wherein the implantation peak position of the implanted work function-regulating doped ions is at the bottom of the gate filling layer close to the first work function metal layer.

Wherein in the second gate stack structure, the second work function metal layer is located at an upper part of the interface between the first work function metal layer and the gate insulating layer.

Wherein in the second gate stack structure, a metal ion diffusion blocking layer is further comprised between the gate filling layer and the first work function metal layer, and the material thereof comprises at least one of oxide, nitride, Si:C, SiGe, amorphous silicon, low-temperature polysilicon, Ge, metal or metal alloy, and metal nitride.

Wherein the substrate comprises at least one of silicon, germanium, strained silicon, germanium-silicon, compound semiconductor, and C-based semiconductor materials.

The present invention also provides a method for manufacturing a semiconductor device, comprising the steps of: forming a plurality of source and drain regions in a substrate; forming a plurality of gate spacer structures on the substrate, wherein the gate spacer structures enclose a plurality of first gate trenches and a plurality of second gate trenches, and there is an interlayer dielectric layer around the gate spacer structures; sequentially depositing a first gate insulating layer and a second gate insulating layer, a first work function metal layer, and a second work function metal diffusion blocking layer in the first and second gate trenches; performing selective etching to remove the second work function metal diffusion blocking layer from the second gate trenches to expose the first work function metal layer; depositing a gate filling layer on the second work function metal diffusion blocking layer in the first gate trenches and on the first work function metal layer in the second gate trenches; implanting work function-regulating doped ions into the bottom of the gate filling layer in the second gate trenches to form a second work function metal layer; and diffusing the work function-regulating doped ions into the first work function metal layer below to jointly change the second gate work function of the second gate stack structure, such that the second gate work function is opposite to the first gate work function of the first gate stack structure.

Wherein the first and/or the second gate insulating layer comprises at least one of silicon oxide, nitrogen-doped silicon oxide, silicon nitride, and high-K materials. Wherein the high-K materials include Hf-based materials selected from HfO₂, HfSiOₓ, HfSiON, HfAlOₓ, HfTaOₓ, HfLaOₓ, HfAlSiOₓ, and HfLaSiOₓ, rare-earth based high-K dielectric materials selected from ZrO₂, La₂O₃, LaAlO₃, TiO₂, and Y₂O₃, Al₂O₃, or a composite layer of the above materials.

Wherein the first work function metal layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La.

Wherein the second work function metal diffusion blocking layer comprises at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W.

Wherein the gate filling layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La; and/or c) metal silicide, including at least one of CoSi₂, TiSi₂, NiSi, PtSi, NiPtSi, CoGeSi, TiGeSi, and NiGeSi; and/or d) metal oxide conductor, including at least one of In₂O₃, SnO₂, ITO, and IZO; and/or e) semiconductor materials, including at least one of doped polysilicon, amorphous silicon, polycrystalline germanium, and polycrystalline silicon-germanium; or a composite layer of the above materials.

Wherein as for a NMOS, the work function-regulating doped ions comprise at least one of Al, Ga, In, and B; as for a PMOS, the work function-regulating doped ions comprise at least one of Sb, As, P, N, and Ar.

Wherein the second work function metal layer is located at an upper part of the interface between the first work function metal layer and the gate insulating layer.

Wherein an annealing or a deposition process is adopted to diffuse the work function-regulating doped ions into the first work function metal layer below.

Wherein the annealing temperature is not higher than 550° C., and the annealing time is not longer than 30 minutes.

Wherein the deposition process comprises deposition of multiple gate filling layers, deposition of a gate dielectric layer, and annealing reflow.

Wherein prior to the deposition of gate filling layers, further comprising depositing a metal ion diffusion blocking layer on the first work function metal layer in the second gate trenches.

In accordance with the semiconductor device and the method of manufacturing the same in the present invention, a second work function metal layer comprised of aggregation of implanted ions is formed in a NMOS metal gate stack by an individual ion implantation, thus the metal work function is effectively regulated with accuracy, the device threshold is controlled simply and efficiently, and the device performance is also enhanced.

### BRIEF DESCRIPTION OF THE DRAWINGS

The technical solutions of the present invention will be described in detail below with reference to the accompanying drawings.

FIG. 1 is a diagrammatic cross-section of a gate-last MOSFET of the prior art; and

FIGS. 2-10 are diagrammatic cross-sections of the steps of the method for manufacturing a MOSFET in accordance with the present invention.

### DETAILED DESCRIPTION OF THE EMBODIMENTS

The features of the technical solutions of the present invention and the technical effects thereof are explained in detail in combination with the illustrative embodiments with reference to the drawings below, and a new type of CMOSFET capable of effectively regulating a metal gate work function to thereby control the threshold and a method of manufacturing the same are disclosed. It shall be noted that like reference signs indicate like structures, and the terms like “first”, “second”, “on” and “below” etc. used in the present application may be used to modify various device structures or manufacturing processes. Unless specific explanations, such modifications do not imply the spatial, sequential or hierarchical relationships of the device structures or manufacturing processes.

The steps of the method for manufacturing a MOSFET in accordance with the present invention will be described in detail with reference to the diagrammatic cross-sections in FIGS. 2-10, wherein, particularly the method is preferably adaptable to the gate-last process.

First, referring to FIG. 2, a CMOS basic structure is formed, that is, at least a first MOSFET and at least a second MOSFET are formed in the substrate comprising STIs, respectively. Wherein the first MOSFET comprises first source and drain regions, first source and drain extension regions, a first gate insulating layer, first gate spacers, first metal silicides, a first contact etch stop layer, and a first interlayer dielectric layer, and the second MOSFET comprises second source and drain regions, second source and drain extension regions, a second gate insulating layer, second gate spacers, second metal silicides, a second contact etch stop layer, and a second interlayer dielectric layer. The first MOSFET is of an opposite to the second MOSFET, for example, if the first MOSFET is a PMOS, the second MOSFET is a NMOS, if the first MOSFET is a NMOS, the second MOSFET is a PMOS. Likewise, the definitions of the materials, structures or characteristics involving “first” and “second” can all be mutually exchanged.

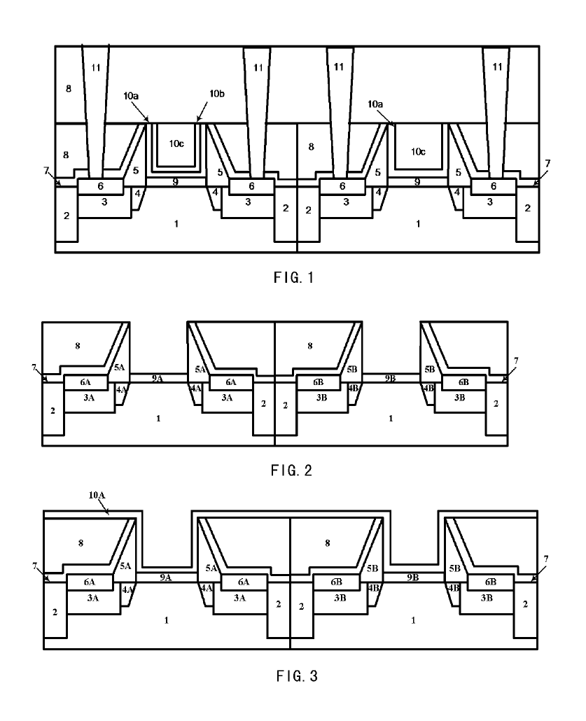

Specifically, a substrate 1 is provided first. The substrate 1 shall be reasonably selected depending on the usage of the device and may comprise single crystalline bulk silicon (Si), silicon on insulator (SOI), single crystalline bulk germanium (Ge), germanium on insulator (GeOI), stained Si, SiGe, or compound semiconductor materials such as GaN, GaAs, InP, InSb, and C-based semiconductors such as graphene, SiC and carbon nanotube. As shown in FIG. 1, the substrate are of a block shape with the first MOSFET and the second MOSFET adjacently formed therein, but the two devices may also be separately formed, e.g., formed at well regions (not shown) of different conductivity types or formed with other separation electronic elements or structures located between them.

Second, shallow trench isolations (STIs) 2 are formed in the substrate 1. For example, photolithography/etching is performed firstly to form shallow trenches in the substrate 1, then an insulating isolation material is deposited by a conventional technique such as LPCVD and PECVD and planarized by chemical mechanical polishing (CMP) to expose the substrate 1, thereby forming STIs 2. Wherein the filling material for STIs 2 may be oxide, nitride, or oxynitride. As shown in the FIG., SITs 2 divide the enclosed substrate 1 into at least a first MOSFET active region and at least a second MOSFET active region, selective deposition and etching will be performed to the two regions in the following process to thereby form devices of different types.

Third, a pad oxide layer and a pseudo gate layer are sequentially deposited on the surface of the entire wafer (i.e., the surface of the substrate 1 and STIs 2) and etched to form first and second pseudo gate stack structures (not shown). The first and second pseudo gate stack structures will be removed in the following process, so the pad oxide layer is preferably silicon oxide, and the pseudo gate layer is preferably polysilicon, amorphous silicon or microcrystalline silicon, even silicon oxide. The width and thickness of the first and second pseudo gate stack structures are set depending on the layout design rules for the PMOS and NMOS and the requirements of the device conductivity characteristics.

Then, first and second pseudo spacers (not shown) are formed on both sides of the first and second pseudo gate stack structures, respectively. For example, a spacer material layer formed of silicon oxide, silicon nitride, or a composite layer thereof is deposited on the device surface and then etched to form the pseudo gate spacers.

Next, first source and drain regions 3A and second source and drain regions 3B are formed in the substrate 1 on both sides of the pseudo gate spacers, respectively. Source and drain regions 3A/3B in traditional processes may be formed by respectively performing a first source and drain ion implantation to the substrate 1 using different masks so as to selectively implant doped ions of different conductivity types, e.g., to implant p-type impurities to the first MOSFET active region and to implant n-type impurities to the second MOSFET active region. In a preferred embodiment of the present invention, source and drain regions 3A/3B may be embedded strained source and drain regions, that is, the first MOSFET active region and second MOSFET region in the substrate 1 are etched by taking the first and second pseudo gate spacers as masks respectively to form first and second source and drain grooves (not shown), then high stress materials such as SiGe or Si:C which are different from the material of the substrate 1 are selectively epitaxially grown in the first and second source and drain grooves, to thereby form embedded stained source and drain regions of the corresponding material. Wherein the upper surface of the embedded strained source and drain regions 3A/3B is not limited to be flush with that of the substrate 1 as shown in FIG. 2, but may be higher than the upper surface of the substrate 1 to form raised sources and drains. Preferably, doped ions may also be implanted to the embedded strained source and drain regions 3A/3B to regulate the type and concentration, or in-situ doping may be performed while the above embedded sources and drains are formed. If the first MOSFET corresponds to the PMOS, the source and drain regions 3A are embedded strained SiGe (e-SiGe) with boron, aluminum, gallium and indium etc. doped, and if the second MOSFET corresponds to the NMOS, then the source and drain regions 3B are embedded strained Si:C (e-SiC) with phosphorus, arsenic, and antimony etc. doped, and vice versa.

Afterwards, the first or second pseudo gate spacers are respectively removed and first source and drain extension regions 4A or second source and drain extension regions 4B are formed in the substrate 1 on both sides of the first or second pseudo gate stack structure, respectively. Pseudo gate spacers formed of silicon nitride or silicon oxynitride may be removed by wet etching, then a second source and drain ion implantation is performed to form lightly doped (LDD) source and drain extension regions 4A/4B. Wherein the conductivity types of the source and drain extension regions 4A/4B are respectively the same as those of the source and drain regions 3A/3B, but the source and drain extensions regions 4A/4B have a lower doping concentration and a shallower junction depth.

Then, first gate spacer structures 5A and second gate spacer structures 5B are formed on both sides of the first and second pseudo gate stack structures, respectively. The gate spacer structures 5A/5B may be made from conventional materials such as silicon oxide (SiOx), silicon nitride (SiNx, x may be 1˜2, and is not limited to an integer), silicon oxynitride (SiOₓN_{y}, x and y may be reasonably adjusted depending on requirements), or a combination thereof Or, preferably, the first and/or the second gate spacer structures 5A/5B may be at least two-layer laminated structure, e.g., low stress gate spacer materials such as silicon oxide (SiOx), silicon nitride (SiNx, x may be 1˜2, and is not limited to an integer), silicon oxynitride (SiOₓN_{y}, x and y may be reasonably adjusted depending on requirements), or a stack comprised of these materials may be deposited on the device surface by a conventional process, then the mask layout and the etching process parameters are controlled to make the low stress gate spacers obtained by etching have an L-shaped cross-section, namely comprising a vertical part which directly contacts the pseudo gate stack structure, and a horizontal part which directly contacts the embedded strained source and drain regions 3A/3B and/or source and drain extension regions 4A/4B. The first gate spacers 5A are used a buffer layer for high stress spacers with a preferred thickness of about 1˜25 nm (a thinner thickness will be helpful to pass a stress). After low stress gate spacers are formed, the high stress gate spacers are then formed. A diamond-like amorphous carbon (DLC) thin film with higher intrinsic stress is formed by a low temperature process such as filtered cathodic vacuum arc (FCVA), PECVD, and magnetron sputtering, then O₂ and/or Ar plasma dry etching is used to form the high stress gate spacers on the horizontal part of the low stress gate spacers and enable the cross-section to be approximately a triangle or a ¼ ellipse. Wherein since the material characteristics of the DLC thin film greatly depend on the content of sp³ bonds, a higher content of sp³ bonds could make the DLC structure more like diamond than graphite. Therefore, in order to increase the intrinsic stress, the process parameters are controlled to make the content of sp3 bonds in DLC be at least greater than 50%, the content of hydrogen atoms be less than 40%, and the content of nitrogen atoms be less than 20%, such that the DLC thin film, which is used as the high stress gate spacer, may have an intrinsic stress not less than 2 GPa, preferably 4˜10 GPa in a preferred embodiment of the present invention. The high stress gate spacers may have a preferred thickness of about 2˜60 nm, and such high stress gate spacers can provide a much higher stress to the channel region, to thereby increase the carrier mobility and improve the device performance. As for an nMOS, the DLC thin film has tensile stress, while for a pMOS, the DLC thin film has compressive stress, thus the high stress gate spacer in the process for manufacturing a CMOS device shall be formed at two times so as to control the type and intensity of the stress, respectively.

Thereafter, a self-aligned silicide process is performed by respectively taking the first and second gate spacers 5A/5B as masks, and a thin film of metal such as Pt, Co, Ni and Ti or metal alloy is deposited on the entire device surface, then a high temperature annealing process is performed such that the silicon contained in the embedded strained source and drain regions 3A/3B reacts with the metal to produce first/second source and drain contact metal silicides 6A/6B such as CoSi₂, TiSi₂, NiSi, PtSi, NiPtSi, CoGeSi, TiGeSi, and NiGeSi so as to decrease the source and drain contact resistance, thereby to further improve the device performance.

Upon formation of the source and drain contact metal silicides 6A/6B, deposition is performed on the entire device surface to form a contact etch stop layer (CESL) 7, that is, CESL 7 is on the STIs 2, source and drain contact metal silicides 6A/6B, gate spacers 5A/5B, and pseudo gate structures, the materials thereof may be a traditional high stress material of SiOₓ or SiNₓ, or the aforesaid high stress DLC. CESL 7 further improves the stress intensity, thus further increase the stress in the channel region. Specifically, the so-called high stress of CESL 7 in the present invention is that the intrinsic stress of the material is greater than 1 GPa, preferably between 2˜10 GPa.

An interlayer dielectric layer (ILD) 8 is deposited for the gate-last process, the layer may be made from silicon oxide, phosphorosilicate glass, F-doped silicon oxide, C-doped silicon oxide, silicon nitride, low-K dielectric materials, or a multi-layer composite layer thereof; a process such as CMP and dry etching is used to planarize the ILD 8 such that its upper surface is flush with the top of the pseudo gate stack structure.

The first and second pseudo gate stack structures are removed by wet etching, to leave first and second gate trenches, as shown in FIG. 2. Then, silicon oxide, nitrogen-doped silicon oxide, silicon nitride, or other high-K materials are respectively deposited in the first and second gate trenches by a process such as PECVD, HDPCVD, and ALD, to form a first gate insulating layer 9A and a second gate insulating layer 9B. The gate insulating layer 9A/9B may only be located at the bottom of the first and second gate trenches, respectively, or be located at the bottom and sidewall of the gate trenches. The high-K materials used by the gate insulating layer 9A/9B include but not limited to Hf-based materials selected from HfO₂, HfSiOₓ, HfSiON, HfAlOₓ, HfTaOₓ, HfLaOₓ, HfAlSiOₓ, and HfLaSiOₓ, rare-earth based high-K dielectric materials selected from ZrO₂, La₂O₃, LaAlO₃, TiO₂, and Y₂O₃, Al₂O₃, or a composite layer of the above materials. Preferably, there is an interface layer (not shown in layers) made from low-K materials between the gate insulating layer 9A/9B made from high-K materials and the substrate 1 to reduce the interface defects, the material of the layer may be, e.g., at least one of silicon oxide, nitrogen-doped silicon oxide, and silicon nitride.

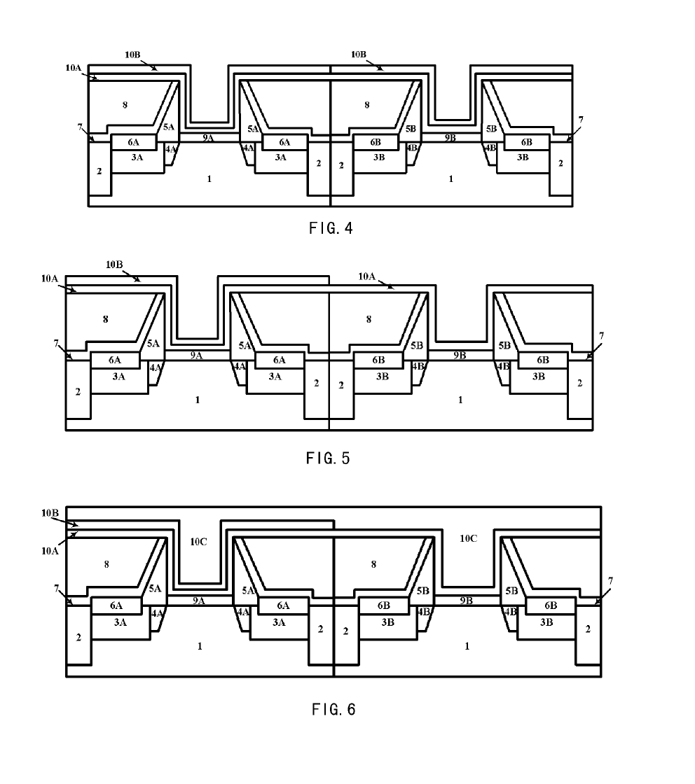

So far, the basic structure as shown in FIG. 2 has already been formed, and the technological process of implanting metal diffusion gates of the present invention will be further described in detail below by referring to FIGS. 3-10.

Next, referring to FIG. 3, a first work function metal layer 10A is deposited on the first and second gate insulating layers 9A/9B in the first and second gate trenches by a conventional process such as PVD, CVD and ALD. The first work function metal layer 10A may comprise a) metal nitride such as MₓN_{y}, MₓSi_{y}N_{z}, MₓAl_{y}N_{z}, and MₐAlₓSi_{y}N_{z}, wherein M is Ta, Ti, Hf, Zr, Mo, W or other elements; and/or b) metal or metal alloy, such as Co, Ni, Cu, Al, Pd, Pt, Ru, Re, Mo, Ta, Ti, Hf, Zr, W, Ir, Eu, Nd, Er, and La, and wherein elements such as C, F, N, O, B, P, As may be doped.

Subsequently, referring to FIG. 4, a second work function metal diffusion blocking layer 10B is deposited on the first work function metal layer 10A by a conventional process such as PVD, CVD and ALD, the material thereof may be MₓN_{y}, MₓSi_{y}N_{z}, MₓAl_{y}N_{z}, and MₐAlₓSi_{y}N_{z}, wherein M is Ta, Ti, Hf, Zr, Mo, W, or other elements. Preferably, the first work function metal layer 10A and the second work function metal diffusion blocking layer 10B may adopt not only a stacked composite layer structure but also adopt a mixed structure, that is, the materials for forming the first work function metal layer 10A and the material for forming the second work function metal diffusion blocking layer 10B are simultaneously deposited on the gate insulating layers 9A/9B, thus the gate material layer comprises the materials of the above blocking layer.

Then, referring to FIG. 5, a part of the second work function metal diffusion blocking layer 10B on the second MOSFET is selectively etched to expose the first work function metal layer 10A in the second gate trenches. For example, a hard mask or photoresist (not shown) is used to cover the first MOSFET, and then wet etching or dry etching is used to remove a part of the second work function metal diffusion blocking layer 10B.

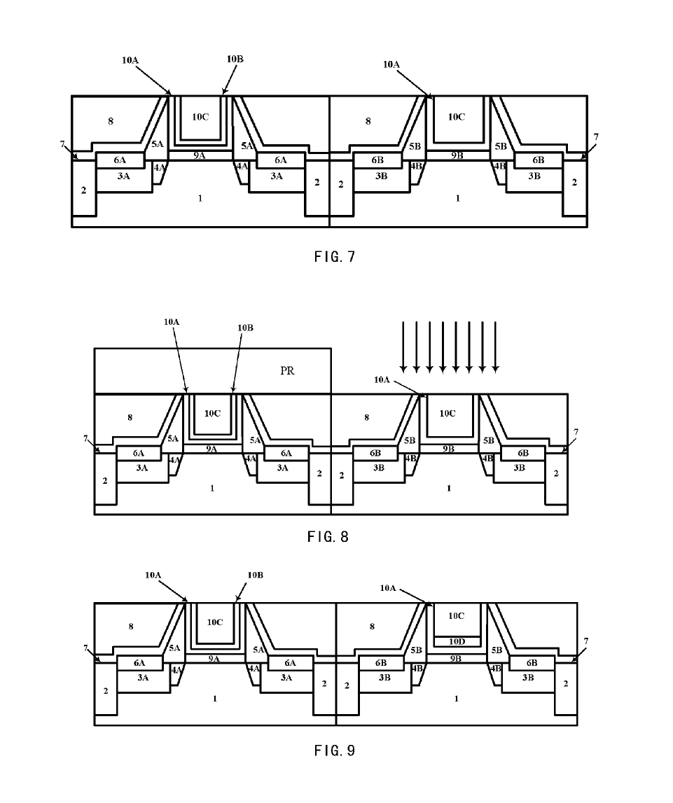

Next, referring to FIG. 6, a high stress gate filling layer 10C is deposited on the first and second MOSFETs by a conventional process such as PVD, CVD and ALD. The gate filling layer 10C may simultaneously function as a second work function diffusion metal layer, the material thereof may include: a) metal nitride, such as MₓN_{y}, MₓSi_{y}N_{z}, MₓAl_{y}N_{z}, and MₐAlₓSi_{y}N_{z}, wherein M is Ta, Ti, Hf, Zr, Mo, W or other elements; b) metal or metal alloy, such as Co, Ni, Cu, Al, Pd, Pt, Ru, Re, Mo, Ta, Ti, Hf, Zr, W, Ir, Eu, Nd, Er, and La; c) metal silicide, such as CoSi₂, TiSi₂, NiSi, PtSi, NiPtSi, CoGeSi, TiGeSi, and NiGeSi; d) metal oxide conductor, such as In₂O₃, SnO₂, ITO, and IZO; e) semiconductor materials, such as doped polysilicon, amorphous silicon, polycrystalline germanium, and polycrystalline silicon-germanium. Preferably, elements such as C, F, N, O, B, P, and As may be doped to regulate the work function, furthermore high-temperature fast annealing, e.g., including laser annealing and spike annealing, is preferably performed on the entire device surface to improve or change the stress. Preferably, the stress of the gate filling layer 10C is made to be greater than 2 GPa.

Subsequently, referring to FIG. 7, the first MOSFET and the second MOSFET are planarized by a process such as CMP to expose the interlayer dielectric layer 8A.

Thereafter, referring to FIG. 8, work function-regulating ion implantation is performed to the second MOSFET. A photoresist (PR) is spin coated on the first MOSFET and the second MOSFET, exposed and developed such that a PR pattern is only left on the first MOSFET. Then, ion implantation is performed to the second MOSFET of a NMOS type, the implanted ions include Al, Ga, In, and B etc. or a combination thereof. The PR is removed afterwards. Likewise, ion implantation may also be performed to the first MOSFET of a PMOS type, and the implanted ions include Sb, As, P, N, and Ar etc. or a combination thereof. The implant distribution peak position of implanted ions is regulated such that it preferably is at the bottom of the gate filling layer 10C, close to the first work function metal layer 10A, e.g., at a place 10±5 nm close to the interface of 10C/10A. Thus, a second work function metal layer 10D having more regulating ions concentration is formed at the bottom of gate filling layer 10C. In other words, the layer 10D is the part of the layer 10C which comprises more work function-regulating ions, e.g., the implantation dose is 1e14˜1e15 cm⁻².

Afterwards, referring to FIG. 9, the ions implanted into the gate filling layer 10C of the second MOSFET are diffused into the bottom or into the first work function metal layer 10A by applying heat energy using an annealing process or a subsequent deposition process, so as to jointly change the gate work function of the second MOSFET. For example, wherein the annealing temperature is not higher than 550° C., and the annealing time is not longer than 30 minutes, and RTA annealing, furnace annealing or laser annealing is used. The subsequent deposition process comprises deposition of multiple gate filling layers, deposition of a gate dielectric layer, and annealing reflow. For example, the gate filling layer 10C is a multi-layer structure, e.g., 10C1/10C2/10C3, wherein the multi-layer structure comprises a combined laminated layer comprising various materials of the above layer 10C, or an interlayer dielectric layer made from insulating materials is further inserted between the layers to form a charge trapping structure so as to be adaptable to the electrically erasable memory such as a flash memory.

Preferably, the peak position of metal ion implantation in the second work function metal layer 10D is close to an upper part of the interface between the first work function metal layer 10A and the gate insulating layer 9B, e.g., at the top of the interface, that is, a laminated structure of 10D/10A/9B is sequentially formed from top to bottom. Or the implantation depth is increased such that the peak of 10D is overlapped with that of 10A. Or, further, the implantation depth is further increased such that the layer 10D is between 10A and 9B, to thereby form a laminated structure of 10A/10D/9B. Preferably, the distance between the layer 10D and the interface of the layer 10A/layer 9B is not greater than 20 nm, and more preferably not greater than 10 nm.

The relative position between the peak for the layer 10D and 10A, 9B may also be changed by adjusting the annealing and the subsequent deposition process conditions, to thereby regulate the work function.

Furthermore, the above annealing process will not only drive the implanted work function-regulating ions to be diffused to the interface of layer 10A/layer 9B downwardly, it will also drive the metal ions in the layer 10C to be diffused to the layer 10A downwardly, to thereby change the work function. The annealing driving depth may be made far smaller than the implantation depth to substantially not change the metal distribution in the layer 10A by controlling a combination of implantation and annealing process parameters etc., e.g., the annealing driving depth is only 1/10˜⅛ of the implantation depth. The technology of a diffusion blocking layer (not shown) may be used. That is, after the layer 10A is exposed by selective etching in FIG. 5, and before deposition of the layer 10C in FIG. 6, a diffusion blocking layer is formed on the layer 10A in the trench of the second MOSFET, the material thereof include at least one of oxide (e.g., SiOₓ), nitride (e.g., SiNₓ), Si:C, SiGe, amorphous silicon (a-Si), low-temperature polysilicon (p-Si), Ge, metal or metal alloy, and metal nitride. Wherein the metal comprises at least one of Co, Ni, Cu, Al, Pd, Pt, Ru, Re, Mo, Ta, Ti, Hf, Zr, W, Ir, Eu, Nd, Er, and La. The metal nitride comprises at least one of MₓN_{y}, MₓSi_{y}N_{z}, MₓAl_{y}N_{z}, and MₐAlₓSi_{y}N_{z}, wherein M is Ta, Ti, Hf, Zr, Mo, W, or other elements. The method for forming the diffusion blocking layer may be, for example, PVD techniques such as evaporation and ALD, or CVD and plating techniques. It should be noted that the heat isolation layer or the diffusion blocking layer shall have a thinner thickness such that a majority of the metal ions in the layer 10C (above the layer 10D) may not be diffused to the layer 10A while the work function-regulating doped ions in the layer 10D can be implanted to the layer 10A smoothly and can be further diffused to the vicinity of the interface between the layer 10A and the layer 9B in the subsequent annealing process. For example, the thickness of the heat isolation layer or the diffusion blocking layer may only be ¼˜½ of that of the second work function metal diffusion blocking layer 10B, e.g., to be only 10 nm specifically. Besides, if the layer 10C is a multi-layer stack structure, the diffusion blocking layer may also be comprised therein, e.g., at the bottom of the layer 10C close to the layer 10A.

The present invention can enable the ions for regulating a work function to arrive at the HK/TiN interface directly by using the individual ion implantation process in cooperation with a corresponding diffusion process, thus can regulate the metal gate work function effectively, control the device threshold, and improve the device performance without using the unstable thickness ratio regulating method in the background art. Particularly, by selecting a first work function metal layer 10A, a second work function metal diffusion blocking layer 10B, a gate filling layer 10C, a second work function metal layer 10D, and the specific material for the implanted ions, as well as the depth of each of the layers, thickness distribution, and annealing conditions, the metal gate work function may be regulated such that, e.g., the first metal gate work function of the first MOSFET is greater than 4.55 eV, preferably greater than or equal to 4.90 eV, to thereby close to the valence band edge 5.15 eV and then correspond to a PMOS, or the second metal gate work function of the second MOSFET is less than 4.55 eV, preferably less than or equal to 4.10 eV, to thereby close to 4.05 eV and then correspond to a NMOS. For example, as for a NMOS, Al ions are implanted, the range peak is 10±5 nm above the interface of the layer 10A and the layer 10C, and the implantation dose is 1e14˜1e15 cm⁻², thus the implanted Al ions can be diffused to an appropriate position in the above annealing process so as to regulate the NMOS metal work function to be less than 4.55 eV and close to 4.05 eV. It should be noted that the specific value of the above work function shall be selected depending on the requirement of the electrical properties of NMOS and PMOS devices, so long as the first gate work function is opposite to the second gate work function, namely, one is close to the valence band and another is close to the conduction band, the specific range of value may be reasonably adjusted.

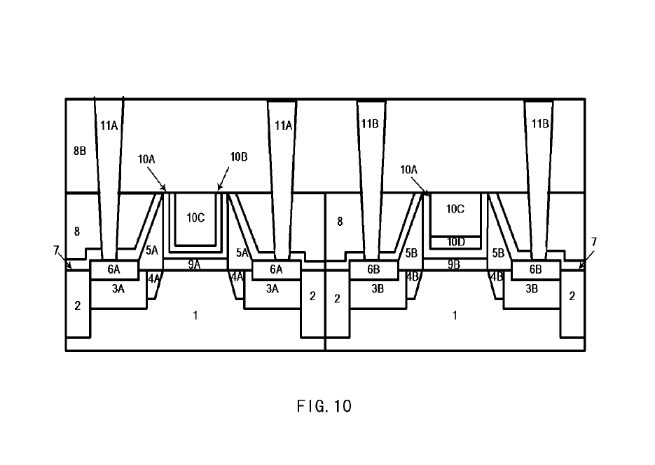

Finally, referring to FIG. 10, device manufacturing is completed. A second interlayer dielectric layer 8B is deposited on the surface of the entire device and is planarized by CMP. The first ILD 8A, the second ILD 8B, and the CESL 7 are etched to form source and drain contact holes so as to expose first and second source and drain contact metal silicides 6A/6B. A contact metal is deposited to form first and second source and drain metal plugs 11A/11B and planarization is performed by CMP to expose the ILD 8B.

The structure of the finally formed semiconductor device is as shown in FIG. 10, comprising a substrate 1, STIs 2, at least a first MOSFET and at least a second MOSFET, wherein the first MOSFET comprises first source and drain regions 3A in the substrate 1, first source and drain extension regions 4A at the inner side of the first source and drain regions 3A, first gate spacers 5A on the first source and drain extension regions 4A, first source and drain contact metal silicides 6A on the first source and drain regions 3A, a first gate stack structure between the first gate spacers 5A on the substrate 1, a contact etch stop layer 7A, interlayer dielectric layers 8/8B, and first source and drain metal plugs 11A passing though the interlayer dielectric layers to be in contact with the source and drain contact metal silicides 6A, the contact etch stop layer 7 being located on the first source and drain contact metal silicides 6A, first gate spacers 5A, and the first gate stack structure, wherein the first gate stack structure sequentially comprises a first gate insulating layer 9A, a first work function metal layer 10A, a second work function metal diffusion blocking layer 10B, and a gate filling layer 10C; wherein the second MOSFET comprises second source and drain regions 3B in the substrate 1, second source and drain extension regions 4B at the inner side of the first source and drain regions 4B, second gate spacers 5B on the second source and drain extension regions 4B, second source and drain contact metal silicides 6B on the second source and drain regions 3B, a second gate stack structure between the second gate spacers 5B on the substrate 1, a contact etch stop layer 7, interlayer dielectric layers 8/8B, and second source and drain metal plugs 11B passing though the interlayer dielectric layers to be in contact with the source and drain contact metal silicides 6B, the contact etch stop layer 7B being located on the second source and drain contact metal silicides 6B, second gate spacers 5B, and the second gate stack structure, wherein the second gate stack structure sequentially comprises a second gate insulating layer 9B, a first work function metal layer 10A, a second work function metal layer 10D, and a gate filling layer 10C. Wherein the specific materials and methods for forming the above layers have been described in detailed in the above manufacturing method, no more unnecessary details will be provided here.

In addition, although the present invention only contain schematic diagrams of an MOSFET having planar channel in the drawings, it will be appreciated by a person skilled in the art that the MOSFET structure of the present invention may also be applied to device structures such as 3D multigates, vertical channel, and nanowire.

In accordance with the semiconductor device and the method of manufacturing the same in the present invention, a second work function metal layer comprised of aggregation of implanted ions is formed in a NMOS metal gate stack by a individual ion implantation, thus the metal work function is effectively regulated with accuracy, the device threshold is controlled simply and efficiently, and the device performance is also enhanced.

Although the present invention has been described with reference to one or more illustrative embodiments, it may be appreciated by a person skilled in the art that various appropriate modifications and equivalents can be made to the device structure without departing from the scope of the present invention. Besides, many modifications adaptable to specific situations or materials can be made under the disclosed teaching without departing from the scope of the present invention. Therefore, the present invention does not aim to define the specific embodiments which are disclosed as the preferred embodiments for implementing the present invention, the disclosed device structure and the manufacturing method thereof will include all the embodiments that fall within the scope of the present invention.

1. A semiconductor device, comprising a substrate, a plurality of gate stack structures on the substrate, a plurality of gate spacer structures on both sides of each gate stack structure, a plurality of source and drain regions in the substrate on both sides of each gate spacer structure, the plurality of gate stack structures comprising a plurality of first gate stack structures and a plurality of second gate stack structures, wherein each of the first gate stack structures comprises a first gate insulating layer, a first work function metal layer, a second work function metal diffusion blocking layer, and a gate filling layer, each of the second gate stack structures comprises a second gate insulating layer, a first work function metal layer, a second work function metal layer, and a gate filling layer, characterized in that the second work function metal layer comprises implanted work function-regulating doped ions, and the work function-regulating doped ions diffuse into the first work function layer to jointly change the work function of the second gate stack structure, such that the second gate work function of the second gate stack structure is opposite to the first gate work function of the first gate stack structure.

2. The semiconductor device according to claim 1, wherein the first gate work function is close to the valence band and the second gate work function is close to the conduction band, or the first gate work function is close to the conduction band and the second gate work function is close to the valence band.

3. The semiconductor device according to claim 1, wherein the first and/or the second gate insulating layer comprises at least one of silicon oxide, nitrogen-doped silicon oxide, silicon nitride, and high-K materials.

4. The semiconductor device according to claim 2, wherein the high-K materials include Hf-based materials selected from HfO₂, HfSiOₓ, HfSiON, HfAlOₓ, HfTaOₓ, HfLaOₓ, HfAlSiOₓ, and HfLaSiOₓ, rare-earth based high-K dielectric materials selected from ZrO₂, La₂O₃, LaAlO₃, TiO₂, and Y₂O₃, Al₂O₃, or a composite layer of the above materials.

5. The semiconductor device according to claim 1, wherein the first work function metal layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La.

6. The semiconductor device according to claim 1, wherein the second work function metal diffusion blocking layer comprises at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W.

7. The semiconductor device according to claim 1, wherein the gate filling layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La; and/or c) metal silicide, including at least one of CoSi₂, TiSi₂, NiSi, PtSi, NiPtSi, CoGeSi, TiGeSi, and NiGeSi; and/or d) metal oxide conductor, including at least one of In₂O₃, SnO₂, ITO, and IZO; and/or e) semiconductor materials, including at least one of doped polysilicon, amorphous silicon, polycrystalline germanium, and polycrystalline silicon-germanium; or a composite layer of the above materials.

8. The semiconductor device according to claim 1, wherein as for an NMOS, the work function-regulating doped ions comprise at least one of Al, Ga, In, and B; as for a PMOS, the work function-regulating doped ions comprise at least one of Sb, As, P, N, and Ar.

9. The semiconductor device according to claim 1, wherein the implantation peak position of the implanted work function-regulating doped ions is at the bottom of the gate filling layer close to the first work function metal layer.

10. The semiconductor device according to claim 1, wherein, in the second gate stack structure, the second work function metal layer is located at an upper part of the interface between the first work function metal layer and the gate insulating layer.

11. The semiconductor device according to claim 1, wherein, in the second gate stack structure, a metal ion diffusion blocking layer is further comprised between the gate filling layer and the first work function metal layer, and the material thereof comprises at least one of oxide, nitride, Si:C, SiGe, amorphous silicon, low-temperature polysilicon, Ge, metal or metal alloy, and metal nitride.

12. The semiconductor device according to claim 1, wherein the substrate comprises at least one of silicon, germanium, strained silicon, germanium-silicon, compound semiconductor, and C-based semiconductor materials.

13. A method for manufacturing a semiconductor device, comprising the steps of:
forming a plurality of source and drain regions in a substrate;
forming a plurality of gate spacer structures on the substrate, wherein the gate spacer structures enclose a plurality of first gate trenches and a plurality of second gate trenches, and there is an interlayer dielectric layer around the gate spacer structures;
sequentially depositing a first gate insulating layer and a second gate insulating layer, a first work function metal layer, and a second work function metal diffusion blocking layer in the first and second gate trenches;
performing selective etching to remove the second work function metal diffusion blocking layer from the second gate trenches to expose the first work function metal layer;
depositing a gate filling layer on the second work function metal diffusion blocking layer in the first gate trenches and on the first work function metal layer in the second gate trenches;
implanting work function-regulating doped ions into the bottom of the gate filling layer in the second gate trenches to form a second work function metal layer; and
diffusing the work function-regulating doped ions into the first work function metal layer below to jointly change the second gate work function of the second gate stack structure, such that the second gate work function is opposite to the first gate work function of the first gate stack structure.

14. The method for manufacturing a semiconductor device according to claim 13, wherein the first and/or the second gate insulating layer comprises at least one of silicon oxide, nitrogen-doped silicon oxide, silicon nitride, and high-K materials.

15. The method for manufacturing a semiconductor device according to claim 14, wherein the high-K materials include Hf-based materials selected from HfO₂, HfSiOₓ, HfSiON, HfAlOₓ, HfTaOₓ, HfLaOₓ, HfAlSiOₓ, and HfLaSiOₓ, rare-earth based high-K dielectric materials selected from ZrO₂, La₂O₃, LaAlO₃, TiO₂, and Y₂O₃, Al₂O₃, or a composite layer of the above materials.

16. The method for manufacturing a semiconductor device according to claim 13, wherein the first work function metal layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La.

17. The method for manufacturing a semiconductor device according to claim 13, wherein the second work function metal diffusion blocking layer comprises at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W.

18. The method for manufacturing a semiconductor device according to claim 13, wherein the gate filling layer comprises: a) metal nitride, including at least one of MₓN_{y}, MₓSi_{y}N_{z}, MₓAl_{y}N_{z}, and MₐAlₓSi_{y}N_{z}, wherein M is at least one of Ta, Ti, Hf, Zr, Mo, and W; and/or b) metal or metal alloy, including at least one of Co, Ni, Cu, Al, Pd, Pt, Ru, Re, Mo, Ta, Ti, Hf, Zr, W, Ir, Eu, Nd, Er, and La; and/or c) metal silicide, including at least one of CoSi₂, TiSi₂, NiSi, PtSi, NiPtSi, CoGeSi, TiGeSi, and NiGeSi; and/or d) metal oxide conductor, including at least one of In₂O₃, SnO₂, ITO, and IZO; and/or e) semiconductor materials, including at least one of doped polysilicon, amorphous silicon, polycrystalline germanium, and polycrystalline silicon-germanium; or a composite layer of the above materials.

19. The method for manufacturing a semiconductor device according to claim 13, wherein as for an NMOS, the work function-regulating doped ions comprise at least one of Al, Ga, In, and B; as for a PMOS, the work function-regulating doped ions comprise at least one of Sb, As, P, N, and Ar.

20. The method for manufacturing a semiconductor device according to claim 13, wherein the second work function metal layer is located at an upper part of the interface between the first work function metal layer and the gate insulating layer.

21. The method for manufacturing a semiconductor device according to claim 13, wherein an annealing or a deposition process is adopted to diffuse the work function-regulating doped ions into the first work function metal layer below.

22. The method for manufacturing a semiconductor device according to claim 21, wherein the annealing temperature is not greater than 550° C., and the annealing time is not greater than 30 minutes.

23. The method for manufacturing a semiconductor device according to claim 21, wherein the deposition process comprises deposition of multiple gate filling layers, deposition of a gate dielectric layer, and annealing reflow.

24. The method for manufacturing a semiconductor device according to claim 13, wherein prior to the deposition of gate filling layers, further comprising depositing a metal ion diffusion blocking layer on the first work function metal layer in the second gate trenches.
